(19) United States
(12) Patent Application Publication
(10) Pub. No.: US 2025/0202065 A1
(43) Pub. Date: Jun. 19, 2025

(54) BATTERY MODULE

(71) Applicant: SAMSUNG SDI CO., LTD., Yongin-si (KR)

(72) Inventors: Ilya GOMBATS, Graz (AT); Lukas WALTER, Graz (AT)

(21) Appl. No.: 18/890,244

(22) Filed: Sep. 19, 2024

(30) Foreign Application Priority Data
Dec. 14, 2023 (EP) 23216902.9

(51) Int. Cl. H01M 50/503; H01M 50/204; H01M 50/519; H05K 1/02

(52) U.S. Cl. CPC H01M 50/503; H01M 50/204; H01M 50/519; H05K 1/0277; H05K 2201/09063

(57) ABSTRACT

A battery module includes a plurality of battery cells stacked along a longitudinal direction and a flexible interconnect configured to provide electrical information of battery cells to a battery management unit. The flexible interconnect extends in the longitudinal direction and is affixed to the plurality of battery cells and includes a plurality of interconnect traces and a stress relief section extending in the longitudinal direction. The stress relief section has a cutout extending along the longitudinal direction that separates adjacent interconnect traces from each other. The interconnect traces include a first peripheral interconnect trace forming a recessed portion and a second peripheral interconnect trace opposite to the first peripheric interconnect trace and forming a protruding portion. A height of the protruding portion in the stress relief section is the same size as or smaller than a width of the flexible interconnect neighboring the stress relief section.

### CROSS-REFERENCE TO RELATED APPLICATION

This application claims priority to and the benefit of European Patent Application No. 23216902.9, filed on Dec. 14, 2023, in the European Patent Office, the entire disclosure of which is incorporated herein by reference.

### FIELD OF THE DISCLOSURE

Aspects of embodiments of the present disclosure relate to a battery module.

### TECHNOLOGICAL BACKGROUND

Recently, vehicles (e.g., vehicles for transportation of goods and people) have been developed that use electric power as a source for motion. Such an electric vehicle is an automobile that is propelled by an electric motor using energy stored in rechargeable (or secondary) batteries. An electric vehicle may be solely powered by batteries or may be a hybrid vehicle powered by, for example, a gasoline generator (e.g., the vehicle may include a combination of electric motor and a conventional combustion engine). Generally, an electric-vehicle battery (EVB) (or traction battery) is a battery used to power the propulsion of a battery electric vehicle (BEV). Electric-vehicle batteries differ from starting, lighting, and ignition batteries in that they are designed to provide (or output) power over sustained periods of time. A rechargeable (or secondary) battery differs from a primary battery in that it is designed to be repeatedly charged and discharged, while the latter provides an irreversible conversion of chemical to electrical energy. Low-capacity rechargeable batteries may be used as a power supply for small electronic devices, such as cellular phones, notebook computers, and camcorders, while high-capacity rechargeable batteries may be used as a power supply for hybrid vehicles and the like.

Generally, rechargeable batteries include an electrode assembly including a positive electrode, a negative electrode, and a separator interposed between the positive and negative electrodes, a case receiving (or accommodating) the electrode assembly, and an electrode terminal electrically connected to the electrode assembly. An electrolyte solution is injected into the case to enable charging and discharging of the battery via an electrochemical reaction between the positive electrode, the negative electrode, and the electrolyte solution. The shape of the case, such as a cylindrical or rectangular shape, may be varied based on the battery's intended purpose. Lithium-ion (and similar lithium polymer) batteries, widely known via their use in laptops and consumer electronics, are the most common type of battery powering the most recent electric vehicles in development.

Rechargeable batteries may be used as (e.g., may be a part of) a battery module including (or formed of) a plurality of unit battery cells coupled to each other in series and/or in parallel to provide high energy density, such as for motor driving of a hybrid vehicle. For example, the battery module may be formed by interconnecting the electrode terminals of the plurality of unit battery cells to each other, the number of unit battery cells depending on a desired amount of power, to realize a high-power rechargeable battery.

Battery modules can be constructed in either a block design or a modular design. In the block design, each battery is coupled to a common current collector structure and a common battery management system, and the unit thereof is arranged in a housing. In the modular design, pluralities of battery cells are connected to form submodules, and several submodules are connected to form the battery module. In automotive applications, battery systems often consist of a plurality of battery modules connected to each other in series to provide a desired voltage. The battery modules may include submodules with a plurality of stacked battery cells, and each stack may include cells connected in parallel that are, in turn, connected in series (XpYs) or cells connected in series that are, in turn, connected in parallel (XsYp).

A battery pack is a set of any number of (often identical) battery modules. They may be configured in a series, parallel or a mixture of both to deliver the desired voltage, capacity, or power density. Battery packs include the individual battery modules and the interconnects, which provide electrical conductivity between them.

A battery system may include a battery management system (BMS), which is a suitable electronic system configured to manage the rechargeable battery, battery module, and battery pack, such as by protecting the rechargeable batteries from operating outside their safe operating area, monitoring their states, calculating secondary data, reporting that data, controlling their environment, authenticating them, and/or balancing them. For example, the BMS may monitor the state of the rechargeable battery as represented by voltage (e.g., total voltage of the battery pack or battery modules and/or voltages of individual cells), temperature (e.g., an average temperature of the battery pack or battery modules, coolant intake temperature, coolant output temperature, and/or temperatures of individual cells), coolant flow (e.g., flow rate and/or cooling liquid pressure), and current. Additionally, the BMS may calculate values based on the above parameters, such as minimum and maximum cell voltage, state of charge (SOC) or depth of discharge (DOD) to indicate the charge level of the battery, state of health (SOH; a variously-defined measurement of the remaining capacity of the battery as % of the original capacity), state of power (SOP; the amount of power available for a defined time interval given the current power usage, temperature, and other conditions), state of safety (SOS), maximum charge current as a charge current limit (CCL), maximum discharge current as a discharge current limit (DCL), and internal impedance of a cell (e.g., to determine open circuit voltage).

The BMS may be centralized such that a single controller is connected to the battery cells through a multitude of wires. In other cases, the BMS may be distributed, with a BMS board installed at each cell and only a single communication cable between the battery and a controller. In other cases, the BMS may have a modular construction including a few controllers, each handling a certain number of (e.g., a group of) cells while communicating between the controllers. Centralized BMSs are most economical but are least expandable and are plagued by requiring a multitude of wires. Distributed BMSs are the most expensive but are simplest to install and offer the cleanest assembly. Modular BMSs provide a compromise of the features and drawbacks of the other two topologies.

The BMS may protect the battery pack from operating outside its safe operating area. Operation outside the safe operating area may be indicated by over-current, over-voltage (e.g., during charging), over-temperature, under-temperature, over-pressure, and ground fault or leakage current detection. The BMS may prevent operation outside the battery's safe operating area by including an internal switch (e.g., a relay or solid-state device) which opens if the battery is operated outside its safe operating area, by requesting the devices to which the battery is connected to reduce or even terminate using the battery, and/or by actively controlling the environment, such as through heaters, fans, air conditioning, or liquid cooling.

Static control of battery power output and charging may not be sufficient to meet the dynamic power demands of various electrical consumers connected to the battery system. Thus, steady exchange of information between the battery system and the controllers of the electrical consumers may be employed. This information may include the battery system's actual state of charge (SoC), potential electrical performance, charging ability and internal resistance as well as actual or predicted power demands or surpluses of the consumers. Therefore, battery systems may include a battery management system (BMS) for obtaining and processing such information on a system level and may also include a plurality of battery module managers (BMMs), which are part of the system's battery modules and obtain and process relevant information on a module level. The BMS measures the system voltage, the system current, the local temperature at different places inside the system housing, and the insulation resistance between live components and the system housing, and the BMMs may measure the individual cell voltages and temperatures of the battery cells in a battery module.

The BMS/BMM, also referred to as a battery management unit (BMU), manages the battery pack, such as by protecting the battery from operating outside its safe operating area (or safe operating parameters), monitoring its state, calculating secondary data, reporting that data, controlling its environment, authenticating it and/or balancing it.

To manage or control the battery cells in the battery module or pack, several types of interconnects are utilized. A first type of interconnect is so-called busbars, which connect two or more terminals of battery cells to provide a parallel or serial configuration of the cells. Due to their nature of providing current from/to the cells, busbars are solid and suitable for conducting high currents. Busbars may have a stripe-like shape with a large surface area. The large surface area can carry substantial electric currents. In most applications, busbars are passive components and can be fitted in even very small and cramped installation spaces but, in some cases, they may be active components.

A second type of interconnect relates to signal lines or wires, which are used to transfer electrical information of a cell or sub-module to the BMS/BMU. Due to their nature of carrying signals, those lines may be flexible (e.g., may be implemented as a flexible interconnect, such as a flexible printed circuit (FPC)). Flexible interconnects are used inside the battery module to connect battery cell poles with the battery management unit. The flexible interconnect may extend over the busbars and, in this case, the busbars should have very smooth edges and surfaces, which is difficult to realize and check. A flexible interconnect may be formed as a stack of an isolating (or insulating) base material, a copper layer out of which multiple conducting traces or signal lines may be formed, and an isolating cover layer. The material of the base and the cover layer may relatively very good isolating properties may sufficiently isolate the signal lines while being relatively thin, such as in a range in the tens of micrometers. This isolating cover layer may be a thin layer of an insulating material, such as polyimide (PI), which is mechanically durable. Even though the insulating material is durable from a mechanical point of view, because of its small thickness, it needs to be protected from hazards, such as sharp edges, rough surfaces, stress, and so on. In other words, this durability is limited by the thickness of the layer; in other words, a very thin layer having a single digit micrometer thickness is fragile. Due to the desire to monitor the cell terminals and the generally high number of cells, the flexible interconnect may have a relatively high number of conducting traces, and each trace is connected to a cell terminal or a busbar. In some cases, a cell terminal may be connected to a busbar, which causes it to have the same potential for all connected cell terminals. In this sense, the flexible interconnect may be connected to the busbars to obtain the potential for the cell terminals. If all potentials of all cell terminals are known, the voltage of each cell is known too.

When a flexible interconnect is used for measuring/balancing cell voltages, it mechanically interconnects battery cells or busbars. Over time, primarily due to aging, cells may swell, and thus, cells should be able to expand in size. This variation of size may be considered when designing the flexible interconnect, so that the flexible interconnect may be able to suitably compensate for changes in the distance between two fixation points. In other words, the volume of the package of one battery cell may increase, which causes movement of a single battery cell relative to another adjacent battery cell. Additionally, movement between battery cells may be induced due to vibrations depending on the use case of the battery module, for example, when used in a vehicle. Therefore, because flexible interconnects are usually arranged on top of the busbars, the possibility of a cell swelling may be considered when designing a flexible interconnect.

This can be accomplished by using different methods. One method of compensating for length changes includes using excess length and forming a wave in a z-direction (e.g., a vertical direction), but this method results in difficult assembly. Another method includes creating 2D-shapes for each single interface, but this method creates more waste and the interconnect cannot be placed as precisely. In related art examples, flexibility is realized by the usage of Ω-shapes in the z-direction of the flexible interconnect, one example of which is shown in FIG. 2. For example, FIG. 2 shows a typical implementation of a flexible interconnect according to the related art showing its top surface in a perspective view. For example, the protrusions in vertical direction are easy to recognize, which act as the above-mentioned Ω-shapes in the z-direction. Pad mounting portions for pads or tabs may be provided in the middle of the flexible interconnect to extend longitudinally. This design is difficult to produce, and it is challenging to position the tabs, which are used for connecting the flexible interconnect to a busbar, with good accuracy at the dedicated areas. The waves or Ω-shapes relax after the flexible interconnect is produced and are usually delivered to the pack assembly in a completely flat condition. Thus, a second manual placement is the only possible solution, but this risks damage to the flexible interconnect by pressing them and scratching over sharp edges of the bus bars. Additional plastic parts have been designed and produced for the assembly process. The flexible interconnect after fixation of welding points is always in a stressed condition. While there is a desire to allow for automatic assembly of flexible interconnects by using, for example, a robot-arm, such automated assembly is not compatible with the Ω-shaped flexible interconnect.

An alternative to the Ω-shape in the z-direction is a flat double S-shape, as shown in, for example, FIG. 3. FIG. 3 is a top view of a flexible interconnect according to the related art. Instead of the Ω-shapes in the z-direction shown in FIG. 2, the stress relief section is flat and does not extend in the z-direction but forms a double S-shape in the plane of the flexible interconnect. However, the S-shape requires increasing (e.g., doubling) the width of the flexible interconnect, which would require twice as much space in the battery module or in the battery pack and results in more cut-off (e.g., waste) material during production. More cut off material refers to the fact that the flexible interconnect is usually formed from a single piece of material, and if the final shape of the flexible interconnect has a certain width, the raw material must have at least the same width. Consequently, large portions of the raw material would be cut off as waste.

Another related art design includes a battery module with busbars, a circuit board, and connectors connecting the circuit board with the busbars. In this related art design, all connectors are separately mounted on the circuit board, which is located in the middle on the upper side of the battery module. For example, the connectors have a buffer section with weight-reducing holes, which decrease the bending strength, compressive strength, and tensile strength, and thereby allow deformation, which has a good buffering effect. For these buffering sections, an S-shape, an Ω-shape, and a Z-shape may be used. However, all of these shapes significantly increase the width of the structure, which brings about the problems mentioned above, such as increased space requirements and more cut off material (e.g., more waste).

### SUMMARY

Embodiments of the present disclosure provide a more reliable and compact battery cell contact structure. Further, automatic assembly is possible and waste, and thus costs, are reduced. This may be achieved by providing a flexible interconnect with a planar stress relief section. Further, the width of the flexible interconnect is normal, that is, is not considerably enlarged. Additionally, cost-effective material usage is achieved by reducing cut off material.

The present disclosure is defined by the appended claims and their equivalents. The description that follows is subjected to this limitation. Any disclosure lying outside the scope of the claims and their equivalents is intended for illustrative as well as comparative purposes.

According to an embodiment of the present disclosure, a battery module includes: a plurality of battery cells stacked along a longitudinal direction; and a flexible interconnect configured to provide electrical information of the plurality of battery cells to a battery management unit. The flexible interconnect extends in the longitudinal direction and is affixed to the plurality of battery cells. The flexible interconnect includes: a plurality of interconnect traces; and a stress relief section extending in the longitudinal direction. The stress relief section has a cutout extending along the longitudinal direction and separates adjacent ones of the plurality of interconnect traces from each other. The plurality of interconnect traces includes a first peripheral interconnect trace forming a recessed portion and a second peripheral interconnect trace opposite to the first peripheric interconnect trace and forming a protruding portion. A height of the protruding portion in the stress relief section is the same size as or smaller than a width of the flexible interconnect neighboring the stress relief section.

The stress relief section may be planar.

The cutout may be non-linear.

The height of the protruding portion in the stress relief section may be the same size as or smaller than a width of one of the plurality of interconnect traces.

The width of the flexible interconnect neighboring the stress relief section may be equal to a width of the flexible interconnect in the stress relief section.

The flexible interconnect may further include a pad mounting portion for mounting a pad, which is connected to one of the battery cells. The pad mounting portion may be outside the stress relief section at an edge of the flexible interconnect extending in the longitudinal direction.

The stress relief section may be symmetrical with respect to an axis perpendicular to the longitudinal direction and passing through a center of the stress relief section.

At least two of the plurality of interconnect traces may have the same width.

The stress relief section may include a plurality of non-linear cutouts, each having the same width.

Each of the non-linear cutouts may have a meandering shape, a wave-like shape, an Ω-like shape, a v-like shape, or a w-like shape.

The flexible interconnect may further include a conductor line.

The stress relief section may further include a conductor line.

Each interconnect trace may further include a conductor line.

The flexible interconnect may be a flexible printed circuit.

According to an embodiment of the present disclosure, a battery pack includes a plurality of the battery modules described herein.

Further aspects and features of the present disclosure can be learned from the dependent claims or the following description.

### BRIEF DESCRIPTION OF THE DRAWINGS

Aspects and features of the present disclosure will become apparent to those of ordinary skill in the art by describing, in detail, embodiments thereof with reference to the attached drawings, in which:

FIG. 1 illustrates a schematic partial perspective view of a battery module according to the related art.

FIG. 2 illustrates a schematic partial perspective view of a flexible interconnect according to the related art.

FIG. 3 illustrates a top view of another flexible interconnect according to the related art.

FIG. 4 illustrates a top view of a flexible interconnect according to an embodiment of the present disclosure.

FIG. 5 illustrates a top view of the flexible interconnect shown in FIG. 4 showing a stress relief section.

FIG. 6 illustrates a top view of a stress relief section according to another embodiment of the present disclosure.

FIG. 7 illustrates a top view of a stress relief section according to another embodiment of the present disclosure.

### DETAILED DESCRIPTION

Reference will now be made, in detail, to embodiments, examples of which are illustrated in the accompanying drawings. Aspects and features of the embodiments, and implementation methods thereof, will be described with reference to the accompanying drawings. The present disclosure, however, may be embodied in various different forms and should not be construed as being limited to only the embodiments illustrated herein. Rather, these embodiments are provided as examples so that this disclosure will be thorough and complete and will fully convey the aspects and features of the present disclosure to those skilled in the art.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

The electrical connections or interconnections described herein may be provided by conducting elements, such as those on a PCB or another kind of circuit carrier. The conducting elements may include metallizations, such as surface metallizations and/or pins, and/or may include conductive polymers or ceramics.

According to an embodiment of the present disclosure, a battery module includes a plurality of battery cells and a flexible interconnect for providing electrical information of the plurality of battery cells to a battery management unit (BMU). The flexible interconnect has an elongated shape in the longitudinal direction of the battery module, which defines the longitudinal direction of the flexible interconnect. Elongated, as used herein, refers to having a width and a length, in which the length is larger than the width, for example double width, ten times the width, or 20 times the width, etc. The flexible interconnect is affixed to at least one battery cell. Further, the flexible interconnect includes at least one planar stress relief section extending along the longitudinal direction of the battery module. At least one planar stress relief section includes at least one non-linear (e.g., curved) cutout extending along the longitudinal direction of the flexible interconnect. At least one cutout refers to, for example, a longitudinal opening or hole, beginning from a top-side and ending at a bottom side (e.g., extending entirely through a thickness of the flexible interconnect). For example, the at least one cutout may be a through-hole. Non-linear means, for example, that two points “A” and “B” are not connected by a straight line but are connected in an indirect manner. The connection may be curved or may include edges. The points may be connected by two crossing (e.g., intersecting) lines. A plurality of interconnect traces is divided from each other by the at least one non-linear cutout. Two interconnect traces are formed next to each cutout.

Embodiments of the present disclosure relate to a new form of a relaxing expandable element between solid flexible interconnect pieces by using (or including) cutouts or slots. This may be achieved by forming several parallel double S-shapes having a smaller width compared to the normal (e.g., the average) width of the flexible interconnect to allow relative longitudinal extension between solid parts of the flexible interconnect and a flat design at the same time.

Thereby, a particularly compact design for the flexible interconnect is provided, which is slim (e.g., its width is narrow) and is flexible in a longitudinal direction. Flexible refers to the ability to be compressed and stretched. Compression may also be referred to as compressive stress. Stretching or expanding may also be referred to as tensile stress. Compression and tensioning may occur repeatedly.

Hereinafter, the embodiments illustrated in the drawings will be described in detail.

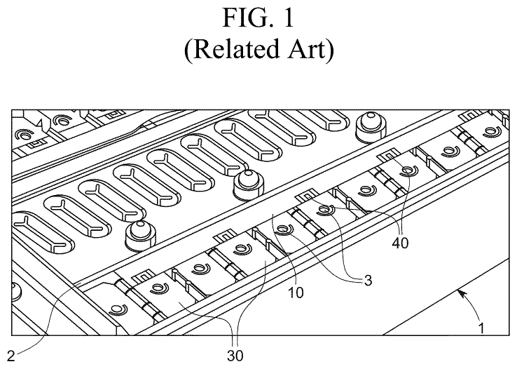

FIG. 1 illustrates a battery module 1 according to the related art. FIG. 1 is a partial perspective view of an upper surface of the battery module 1 in which a plurality of battery cells 2 are arranged in parallel along a longitudinal direction of the battery module 1. The plurality of battery cells 2 are connected to each other by a busbar 30. The busbar 30 connects terminals 3 of battery cells 2. For example, two neighboring battery cells 2 are connected by the busbar 30. A first part of the busbar 30 extends along the longitudinal direction of the battery cell 2, on top of and parallel to the battery cell 2, and two of the first parts are connected to one busbar 30. For example, the busbar 30 extends in the stacking direction of the battery cells. Accordingly, in FIG. 1, reference numeral 30 indicates the first two busbars. The busbar 30 may have a planar structure. On top of the busbar 30, a pad 40 is arranged, which is connected to a flexible interconnect 10. The flexible interconnect 10 extends along the battery module 1 in the longitudinal direction. For example, six busbars 30 each have one pad 40 which are all connected to the same flexible interconnect 10. Thus, the flexible interconnect 10 has at least six signal lines. The number of signal lines formed on the flexible interconnect 10 is equal to the number of busbars 30 connected to the flexible interconnect 10.

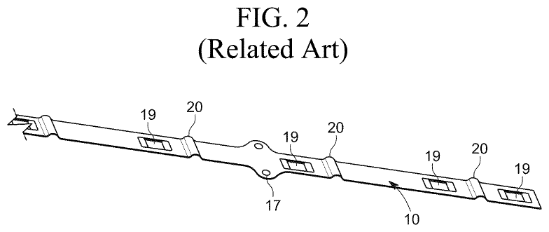

FIG. 2 is a perspective view of an upper surface of a flexible interconnect of a battery cell contacting structure according to the related art. For example, FIG. 2 shows a flexible interconnect 10 and an FPC 12 according to the related art. The flexible interconnect 10 has mounting holes 17 on its sides with a margin for adjustment when placing the flexible interconnect 10. In the middle of the flexible interconnect 10, pad mounting portions 19 may be provided. For example, the flexible interconnect 10 is connected to a busbar 30 (see, e.g., FIG. 1) or a cell terminal 3 (see, e.g., FIG. 1) at the pad mounting portions 19 by a pad or tabs. Signal lines for transferring the electrical information of the battery cells 2 to a battery management system are located on the bottom of the flexible interconnect 10. For example, stress relief sections 20 are formed to extend in vertical direction such that the flexible interconnect 10 is not flat. At least one stress relief portion 20 may be located between two pad mounting portions 19.

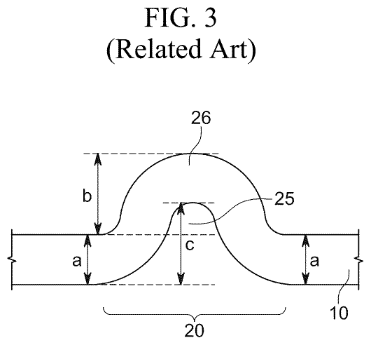

FIG. 3 is a partial top view of a stress relief section 20 of an upper surface of a flexible interconnect 10 in a flat design according to the related art. The flexible interconnect 10 has a width a at the very left and right, and in the stress relief section 20, has a protruding portion 26, protruding by a height b, and a recessed portion 25 on the opposite edge of the flexible interconnect 10 in the stress relief section 20. Throughout this disclosure, the height b is defined and/or measured from an outer edge of the flexible interconnect 10, and the outer edge is parallel to the longitudinal direction of extension of the flexible interconnect 10 to a tangent line parallel to an outer edge of the protruding portion 26, and distanced from the outer edge of the flexible interconnect 10. According to the related art, the height b of the protruding portion is significant, meaning that the value of the height b of the protruding portion is at least close to the width a of the flexible interconnect 10 or much larger than the width a of the flexible interconnect 10. Thus, a depth c of the recessed portion 25 which clearly exceeds the width a of the flexible interconnect 10. For example, an inflection point of the recessed portion 25 exceeds the width a of the flexible interconnect. This results in an increase in an overall width of the flexible interconnect 10, the overall width being width a plus height b. Therefore, the production of this flexible interconnect 10 according to FIG. 3 requires cutoff of significant material on the left and right side of the stress relief section 20, because the flexible interconnect 10 is usually formed integrally out of one piece.

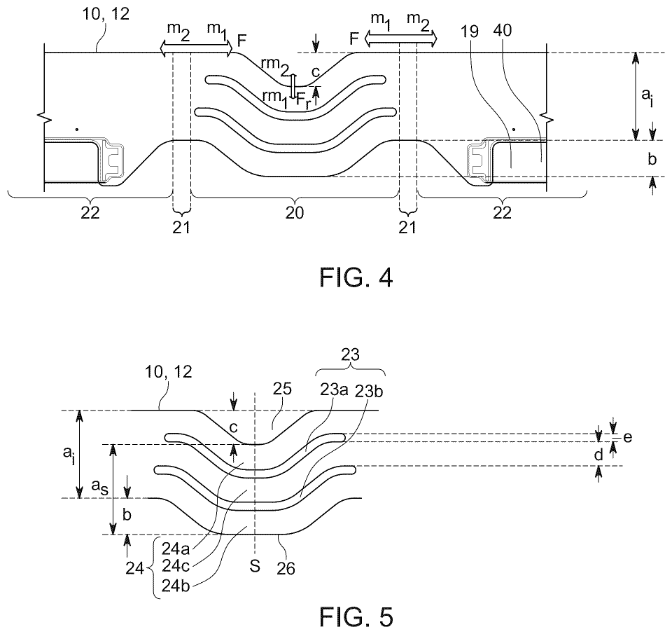

Reference numerals used with respect to FIGS. 4-7 may refer to different structures than structures referenced by the same reference numerals with respect to FIGS. 1-3. FIG. 4 and FIG. 5 are top views illustrating the upper side of a flexible interconnect 10 (e.g., an FPC 12) according to some embodiments of the present disclosure. Referring to FIG. 4 and FIG. 5, according to some embodiments of the present disclosure, the flexible interconnect 10 may be linear and may include a stress relief section 20, which may be referred to as a stress accommodation section. The stress relief section 20 may include a structure configured to absorb stress. The structure may include non-linear cutouts 23 and interconnect traces 24, which will be described in detail below. Main sections 21 of the flexible interconnect 10 may be defined on both ends (e.g., on opposite ends) of the stress relief section 20. The main section 21 has a width aᵢ and, in some embodiments, extends in a longitudinal direction of the flexible interconnect 10. A width aₛ of the flexible interconnect 10 in the stress relief section 20 is not larger than or equal to (e.g., is smaller than) the width aᵢ of the flexible interconnect 10 in the main section 21. The width aₛ of the stress relief section 20 does not include the void or depth c formed by the recessed portion 25 or the height b of the protruding portion 26. The stress relief section 20 is terminated by outer interconnect traces 24a and 24b, for example, at least two outer interconnect traces 24a and 24b, which are described later. The longitudinal direction of the flexible interconnect 10 may be the same as the stacking direction of the battery cells 2, but it is not limited thereto. The width aᵢ and/or aₛ may be in a range from about 2 mm to about 20 mm, about 4 mm to about 15 mm, or about 6 mm to about 10 mm. For example, the width aᵢ and/or aₛ may depend on (or may be determined based on) the number of battery cells 2, for example, based on the number of busbars 30 that have to be connected by the flexible interconnect 10. A width of about 2 mm may be sufficient for small battery modules. A width of about 20 mm may be sufficient for large-scale applications. Even though the main section 21 of the flexible interconnect 10 shown in FIG. 4 is relatively short, the present disclosure is not limited thereto. In other embodiments, the main section 21 may span a longer distance than the stress relief section 20 and/or multiples thereof. A pad mounting section 22, at where a pad 40 may be mounted to the flexible interconnect 10 at the pad mounting portion 19 for connecting the flexible interconnect 10 to the busbar 30 by the pad 40, may be adjacent to the main section 21. For example, the pad mounting section 22 may have a larger width than the main section 21. The pad mounting section 22 may have the same or substantially the same width as the main section 21 or the same or substantially the same width as the stress relief section 20. For example, in an embodiment in which the pad mounting portion 22 is directly attached to the stress relief section 20, the main section 21 may also be a part of the flexible interconnect 10 on a side of a pad mounting structure facing away from the stress relief section 20. For example, the “main section” may refer to the section of the flexible interconnect 10 at where the flexible interconnect 10 extends along the longitudinal direction with its predominant width without any indentations or protrusions. The flexible interconnect 10 may have a rectangular shape in the main section 21. The predominant width refers to the width of the flexible interconnect 10 at a section different from the pad mounting portion 22 and different from the stress relief section 20. For example, more than about 80% of the flexible interconnect 10 has the predominant width.

In another embodiment, the stress relief section 20 may be displaced with respect to the neighboring sections, for example, the main section 21 and/or the pad mounting section 22. Displaced refers to movement or arrangement with respect to the longitudinal direction of the flexible interconnect 10, the stress relief section 20 may be moved away from the original longitudinal direction in the same plane as the flexible interconnect 20. For example, the stress relief section 20 may be moved perpendicular to the longitudinal direction of the flexible interconnect 10. However, the flexible interconnect 20 remains continuous.

FIG. 5 illustrates the stress relief section 20 in more detail. In some embodiments, the stress relief section 20 may include two non-linear cutouts 23 extending along the longitudinal direction of the flexible interconnect 10. The longitudinal extension of the non-linear cutout 23 may be non-linear. Non-linear means that two points are not connected by a straight line. In other words, they are connected in an indirect manner. The non-linear cutouts 23 may be curved and may have a meandering shape or may include two or more straight lines with intersection points therebetween. Meandering riverbeds are common in nature and form a well-known shape. The shape of the stress relief section 20 may also be an Ω-shape, in which the legs of the Ω are partly pulled apart. While the Ω-shape is almost circular, when the lower flat straight portions are pulled apart, the circular shape is flattened and may form the shape depicted in FIGS. 4 and 5. The non-linear cutouts 23 have a width e. The stress relief section 20 may have at least two non-linear cutouts 23. In some embodiments, the width e of each non-linear cutout 23 is identical. In another embodiment, the width e of at least two non-linear cutouts 23 is identical. The width e may be constant throughout the length of the non-linear cutout 23 or may vary. One non-linear cutout 23 separates the flexible interconnect 10 into at least two interconnect traces 24. For example, the stress relief section 20 may have two outer interconnect traces 24a and 24b on its edges. The outer outline of a first outer interconnect trace 24a may form a recessed portion 25. The outer outline of a second outer interconnect trace 24b, opposite to the first outer interconnect trace 24a, may form a protruding portion 26. In the illustrated embodiment, three interconnect traces 24 are formed by two non-linear cutouts 23. In other words, n non-linear cutouts 23 form n+1 interconnect traces 24. The interconnect traces 24 may have a width d. For example, at least two of the interconnect traces 24 have an identical width d. All interconnect traces 24 may have the same or substantially the same width d or may have a different width or a varying width. For example, the outer (or peripheral) interconnect traces 24a and 24b may have the largest width and each inner interconnect trace 24c may have a smaller width. For example, the outer interconnect traces 24a and 24b may have a smaller width than each inner interconnect trace 24c. This would yield flexibility towards the interconnect traces 24 with smaller thickness. The width d may be in a range from about 1 mm to about 10 mm, about 2 mm to about 8 mm, or about 3 mm to about 5 mm. A thickness of about 1 mm provides sufficient strength and is most flexible. On the other end of the range, a thickness of about 10 mm provides very good strength while still being sufficiently flexible. An axis of symmetry S extends through the middle of the stress relief section 20. The flexible interconnect 10 may be symmetrical with respect to the axis of symmetry S. The axis of symmetry S may be an axis perpendicular to the longitudinal direction and may pass through a center (or a center point) of the stress relief section 20. The non-linear cutout 23 may have an s-shape. Because the s-shape extends on both directions of the axis of symmetry S, this shape cutout may be referred to as a double-s-shape cutout. For example, both the non-linear cutouts 23 and the interconnect traces 24 may have a double-s-shape. For example, the shapes of the non-linear cutouts 23 and/or the shapes of the interconnect traces 24 may extend parallel to each other. Even though they may extend parallel to each other, they may be of different sizes and/or lengths, as shown in FIG. 5, where a first outer non-linear cutout 23a is, in a longitudinal direction of the flexible interconnect 10, shorter than a second outer non-linear cutout 23b. In other embodiments, the non-linear cutouts 23 may all or partly have the same or substantially the same length. Furthermore, as shown in FIG. 4 and FIG. 5, the second outer non-linear cutout 23b may have, in the vicinity of the axis of symmetry S, a linear portion that is longer than the linear portion of the first outer non-linear cutout 23a.

Because the non-linear cutout 23 extends non-linearly, a recessed portion 25 and a protruding portion 26 are formed in the flexible interconnect 10. When a force F acts in longitudinal direction (see, e.g., the longitudinal arrows in FIG. 4) on the outer ends of the stress relief section 20, or the outer ends of the flexible interconnect 10, this tension may cause a deformation of the stress relief section 20. This means that a force F may cause an intended (or expected) deformation of the stress relief section 20. For example, stress may be concentrated in the stress relief section 20, and deformation of other parts of the flexible interconnect 20 in an uncontrolled manner may be prevented or substantially reduced. For example, in the event of a compressive stress, which may be caused by movement mi of both ends of the stress relief section 20, one or more interconnecting traces 24 may deform, for example, by a reactive movement rm₁, and the longitudinal ends of the stress relief section 20 may move towards each other in the longitudinal direction of the flexible interconnect 10. Then, the stress relief section 20 is compressed, and the height b of the protruding portion 26 may increase. For example, in the event of tensile stress, which might be caused by a movement m₂, the interconnecting traces 24 may deform, for example, by a reactive movement rm₂, and the longitudinal ends of the stress relief section 20 move away from each other. Then, the stress relief section 20 is flattened, that is, the height b of the protruding portion 26 may become smaller. In the preceding examples, all of the deformations occur in the same plane as the plane which the flexible interconnect 10 extends in. Accordingly, the deformation in a vertical direction (e.g., a direction perpendicular to the longitudinal direction of the flexible interconnect 10 and perpendicular to the width of the flexible interconnect 10) of the flexible interconnect 10 is minimal or zero. According to the embodiment illustrated in FIG. 5, the recessed portion 25 may be formed next to the first outer interconnect trace 24a. In some embodiments, the recessed portion 25 may have a rounded shape, for example, a round or an oval shape. The recessed portion 25 has a depth c. The depth c may be smaller than the width of the flexible interconnect aᵢ. For example, the width c may be in a range from about aᵢ/2 and the width d of the interconnect trace 24. The protruding portion 26 may be formed on the opposite side of the recessed portion 25 (e.g., the opposite side in a direction perpendicular to the extension direction of the flexible interconnect 10). The protruding portion 26 has the height b. In one embodiment, the height b and the depth c may be the same or substantially the same. The recessed portion 25 and the protruding portion 26 refer to portions of the flexible interconnect 10 and define the outer shape of the flexible interconnect 10. According to some embodiments of the present disclosure, the width aₛ of the flexible interconnect 10 in the stress relief section 20 may not be larger than or equal to the width aᵢ of the flexible interconnect 10 in the main section 21. The width aₛ of the flexible interconnect 10 in the stress relief section 20 may be measured by taking an orthogonal onto a tangent along the non-linear outer edge of the first outer interconnecting trace 24a to the opposite outer edge of the second outer interconnecting trace 24b. In the stress relief section 20, the overall expansion of the flexible interconnect 10 in the stress relief section 20 is, when taking the outer edge of the flexible interconnect 10 on the side of the recessed portion 25 as the baseline, width aᵢ plus height b, where width aᵢ refers to the width of the flexible interconnect 10, in the main section 21, (also referred to as the predominant width) and height b refers to the expansion of the protruding potion 26, which exceeds the width aᵢ of the flexible interconnect 10 in the main section 21. In other words, the overall expansion of the flexible interconnect 10 is width aᵢ plus height b. In some embodiments, the height b of the protruding portion 26 may be equal to the width d of the interconnect trace 24. In some embodiments, the height b of the protruding portion 26 may be smaller than the width d of the interconnect trace 24. For example, the height b of the protruding portion 26 in the stress relief section 20 may not be larger than the width d of one interconnect trace 24. The smaller the height b of the protruding portion 26, the more compact the flexible interconnect 10 will be. For example, the smaller the height b of the protruding portion 26, the lower the amount of material to be cut off. On the other hand, the recessed portion 25 does not directly influence the height b of the protruding portion 26 but only defines the depth c. Therefore, in some embodiments, the width aₛ of the flexible interconnect 10 in the stress relief section 20 may be smaller than width aᵢ of the flexible interconnect 10 if the height b of the protruding portion 26 is smaller than depth c. For example, if the width aₛ of the stress relief section 20 is sufficient to accommodate all signal lines, then, the width aₛ of the stress relief section 20 may be smaller than the width aᵢ of the flexible interconnect 10.

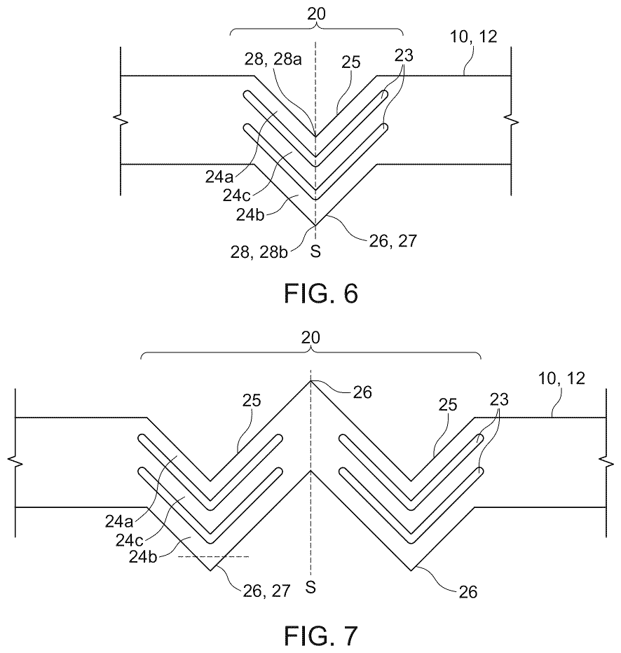

FIG. 6 illustrates another flexible interconnect 10 according to some embodiments of the present disclosure. For example, FIG. 6 is a top view of a stress relief section 20, similar to that shown in FIG. 5. In this embodiment, the stress relief section 20 has a V-shape. The V-shape may have a corner 28 in the axis of symmetry S. For example, a non-linear cutout 23 as well as an interconnect trace 24 may have the corner 28. The corner 28 may be sharp or rounded or the like. The corner 28 in the recessed portion 25 might be referred to as an inner corner 28a. Similarly, the corner 28 in the protruding portion 26 might be referred to as an outer corner 28b. Further, the definitions regarding the stress relief section 20, the main section 21 and the pad mounting section 22 of the above-described embodiments apply. For example, the definitions regarding the height b of the protruding portion 26 apply accordingly. Even though a second outer interconnect trace 24b forming the protruding portion 26 has a sharp tip 27 or the corner 28 in the embodiment illustrated in FIG. 6, this tip 27 or corner 28 may be cut off (see, e.g., FIG. 7) or rounded. Thereby, the height b of the protruding portion 26 may be reduced.

FIG. 7 is a top view of another embodiment of the present disclosure similar to the embodiment in FIG. 6. In this embodiment, the stress relief section 20 has a w-shape. The w-shape might be formed of two V-shapes, as described above. In such an embodiment, the axis of symmetry S extends along the middle of the w-shape. The w-shape may have two protruding portions 26 on the lower side w-shape. In some embodiments, the w-shape may have one additional protruding portions 26 in the middle and on the upper side of w-shape. In such an embodiment, there may be a total of three protruding portions 28. In some embodiments, a non-linear cutout 23 may not be continuous throughout the entire stress relief section 20 but may be intermittent. In some embodiments, the non-linear cutout 23 may be continuous even a longer shape, for example, continuous across the entire w-shape.

It is noted that some of the features indicated by numerals mentioned above are omitted in other sections of the drawings to improve readability. However, it will be clear to those skilled in the art that the cut off corner in FIG. 7 may be applied to all other corners of the present disclosure. Further, it should be kept in mind that many other shapes can be used. For example, the stress relief section 20 is not limited to the shapes described with respect to FIGS. 5-7. For example, other shapes with an axis of symmetry, or even shapes without an axis of symmetry, may be used. For example, any concatenation of simple basic shapes, or the shapes disclosed here, are suitable.

When comparing the embodiments shown in FIG. 5 to FIG. 7, the following differences become apparent. The stress relief section 20, which includes the non-linear cutout 23 and/or the interconnect trace 24, in the embodiment shown in FIG. 5 has a rounded shape, while stress relief sections 20 in the embodiments illustrated in of FIGS. 6 and 7 have a straight (or edged) shape. The rounded shape may distribute the longitudinal stress in a more distributed manner. The straight (or edged) shapes in the embodiments shown in FIGS. 5 and 6 have linear portions and corner portions, which may be easier to manufacture. Comparing the embodiments shown in FIGS. 6 and 7, the V-shape is more compact. On the other hand, the w-shape has the ability to vertically move the protruding portion 26 in the middle. Thus, the deformation properties of the stress relief section 20 can be adjusted. Furthermore, the length of the non-linear cutout may be changed in all embodiments.

For all of the embodiments of the present disclosure, including the embodiments described above, conductor lines may pass through the flexible interconnect 10 in the longitudinal direction. For example, the flexible interconnect 10 may include at least one conductor line. One conductor line connects one pad 40 (see, e.g., FIG. 4) with the other end of the flexible interconnect 10, at where a BMU/BMS may be located. When the flexible interconnect 10 includes a plurality of conductor lines, the conductor lines may be distributed between the interconnect traces 24. For example, in each stress relief section 20, each interconnect trace 24 may include at least one conductor line. For example, one interconnect trace 24 may include a plurality of conductor lines. In such an embodiment, the distances between individual conductor lines are considered when defining the width d of each interconnecting trace 24. Similarly, when defining the width e of a non-linear cutout 23, the degree of deformation of the interconnect traces 24 in the stress relief section 20 should be considered so that the interconnecting traces 24 do not touch each other. In some embodiments, the interconnecting traces 24 may touch, but the flexible interconnect 10 may be designed such that the conducting lines do not come too close and, for example, do not touch each other. Further, it is clear to those skilled in the art that all measurements referred to in this disclosure are measured in a relaxed state, that is, a state not under stress.

### SOME REFERENCE NUMERALS

1 battery module
2 battery cell
3 terminal
10 flexible interconnect
12 flexible printed circuit
17 mounting hole
19 pad mounting portion
20 stress relief section
21 main section
22 pad mounting section
23 non-linear cutout
24 interconnect trace
25 recessed portion
26 protruding portion
27 tip
28 corner
28a outer corner
28b inner corner
30 busbar
40 pad

1 what is claimed is:

1. A battery module comprising:
a plurality of battery cells stacked along a longitudinal direction; and
a flexible interconnect configured to provide electrical information of the plurality of battery cells to a battery management unit, the flexible interconnect extending in the longitudinal direction and being affixed to the plurality of battery cells, the flexible interconnect comprising:
a plurality of interconnect traces; and
a stress relief section extending in the longitudinal direction,
wherein the stress relief section has a cutout extending along the longitudinal direction, the cutout separating adjacent ones of the plurality of interconnect traces from each other,
wherein the plurality of interconnect traces comprises a first peripheral interconnect trace forming a recessed portion and a second peripheral interconnect trace opposite to the first peripheric interconnect trace and forming a protruding portion, and
wherein a height of the protruding portion in the stress relief section is the same size as or smaller than a width of the flexible interconnect neighboring the stress relief section.

2. The battery module as claimed in claim 1, wherein the stress relief section is planar.

3. The battery module as claimed in claim 2, wherein the cutout is non-linear.

4. The battery module as claimed in claim 3, wherein the height of the protruding portion in the stress relief section is the same size as or smaller than a width of one of the plurality of interconnect traces.

5. The battery module as claimed in claim 1, wherein the width of the flexible interconnect neighboring the stress relief section is equal to a width of the flexible interconnect in the stress relief section.

6. The battery module as claimed in claim 2, wherein the flexible interconnect further comprises a pad mounting portion for mounting a pad, which is connected to one of the battery cells,
wherein the pad mounting portion is outside the stress relief section at an edge of the flexible interconnect extending in the longitudinal direction.

7. The battery module as claimed in claim 1, wherein the stress relief section is symmetrical with respect to an axis perpendicular to the longitudinal direction and passing through a center of the stress relief section.

8. The battery module as claimed in claim 1, wherein at least two of the plurality of interconnect traces have the same width.

9. The battery module as claimed in claim 1, wherein the stress relief section comprises a plurality of non-linear cutouts, each having the same width.

10. The battery module as claimed in claim 9, wherein each of the non-linear cutouts has a meandering shape, a wave-like shape, an Ω-like shape, a v-like shape, or a w-like shape.

11. The battery module as claimed in claim 1, wherein the flexible interconnect further comprises a conductor line.

12. The battery module as claimed in claim 1, wherein the stress relief section further comprises a conductor line.

13. The battery module as claimed in claim 1, wherein each interconnect trace further comprises a conductor line.

14. The battery module as claimed in claim 1, wherein the flexible interconnect is a flexible printed circuit.

15. A battery pack comprising a plurality of the battery modules as claimed in claim 1.
